(19) United States
(12) Patent Application Publication
(10) Pub. No.: US 2022/0322532 A1
(43) Pub. Date: Oct. 6, 2022

(54) Three-Dimensional Printed Circuit Substrate Assembly

(71) Applicant: Indiana Integrated Circuits, LLC, South Bend, IN (US)

(72) Inventors: Jerome David Huener, New Carlisle, IN (US); Jason M. Kulick, South Bend, IN (US); Robert Joseph Engelhardt, JR., Broomfield, CO (US)

(21) Appl. No.: 17/713,595

(22) Filed: Apr. 5, 2022

Related U.S. Application Data
(60) Provisional application No. 63/170,641, filed on Apr. 5, 2021.

(51) Int. Cl. H05K 1/14

(52) U.S. Cl. CPC H05K 1/14; H05K 2201/047

(57) ABSTRACT

A substrate assembly includes a number of printed circuit substrates (PCS'). Each PCS includes a first or top surface and a second or bottom surface spaced from each other and an edge that runs at least partially about a periphery of the PCS between the top surface and the bottom surface. The edge of each PCS includes or defines on a facet or edge surface of the edge a number of spaced projections or nodules that extend transverse or normal to the facet or edge surface. The spaced projections or nodules of each pair of the number of PCS' are connected in an interdigitated manner with adjacent or proximate edge surfaces of the pair of PCS' positioned at an angle between 30° and 135° to each other, for example, at an angle of 90° to each other.

### CROSS REFERENCE TO RELATED APPLICATION

This application claims the benefit of U.S. Provisional Patent Application No. 63/170,641, filed Apr. 5, 2021, the contents of which are incorporated herein in its entirety by reference

### BACKGROUND OF THE INVENTION

### Field of the Invention

The present invention relates to substrate assemblies that include multiple printed circuit substrates which are mechanically and, optionally, electrically connected together via projecting or protruding nodules to form three-dimensional (3D) substrate assemblies or structures. Some or all of the substrates can include electrical circuitry Where two or more of the substrates include electrical circuitry, the protruding nodules can include or be made from conductive material that may also serve to electrically connect the electrical circuitry on said two or more substrates.

### Description of Related Art

Historically, interconnecting printed circuit substrates (PCS'), such as one or more printed circuit (or wiring) boards, or one or more integrated circuit chips, or some combination thereof, to form a substrate assembly was accomplished via one or more mechanical connectors or cables used as a mechanical and/or electrical interface between each pair of PCS'.

More recently, Quilt Packaging (QP) interconnect technology (hereinafter “QP”) which utilizes projections or “nodules” that extend from, project, or protrude out from vertical facets along edges of PCS' allow for inter-substrate communication, mechanical fastening, and/or alignment of one or more PCS'. QP enables the interconnection of multiple PCS' fabricated with similar and/or dissimilar technologies or substrate materials to be integrated into a monolithic-like structure.

Due to the nature of the QP manufacturing process, the geometry of the projections or nodules and chips/component substrate are lithographically-defined, which allows for the application/specific definition of the substrate-to-substrate gap and alignment, in addition to overall substrate assembly system architecture. In this regard, QP is a complementary packaging approach to existing interconnecting technologies and may be utilized alone or in combination with existing interconnecting technologies. Details regarding QP and the formation of nodules can be found in U.S. Pat. No. 7,612,443 to Bernstein et al. which is incorporated herein by reference in its entirety.

Heretofore, QP has been used to mechanically and, optionally, electrically interconnect multiple PCS', e.g., first and second PCS', laterally, e.g., in a plane, or substantially laterally or substantially in a plane with vertical facets along edges (or side edges) of the first and second PCS' facing or substantially facing, and parallel or substantially parallel, to each other, with the top surfaces of the first and second PCS' facing or substantially facing upward or in one direction, and with the bottom surfaces of the first and second PCS' facing or substantially facing downward or in a second, opposite direction and, optionally, mounted on a carrier substrate.

There is presently a desire to increase the density of interconnected PCS'. Accordingly, disclosed herein are three-dimensional (3D) substrate assemblies formed using QP.

### SUMMARY OF THE INVENTION

Generally, provided, in some non-limiting embodiments or examples, is a printed circuit assembly formed from a number of PCS' including QP projections or nodules along one or more edges of each PCS, interconnected along their edges via their respective QP nodules to form a 3D substrate assembly or structure where the edges generally face transverse to each other and the 3D substrate assembly or structure may include one or more openings.

In some non-limiting examples or examples, the generally facing transverse edges of each pair of interconnected PCS' may be positioned at (1) an acute angle between, for example, 30° and 90° to each other, between 45° and 90° to each other, or between 60° and 90° to each other, (2) at a right or substantially right (90°) angle to each other, or (3) at an obtuse angle between, for example, 90° and 135° to each other.

In some non-limiting examples or examples, the edge of each PCS may be a peripheral edge of the PCS between a top (or first) surface or face of the PCS and bottom (or second) surface or face of the PCS that faces in a direction opposite the top surface.

In some non-limiting examples or examples, each PCS may include a number of QP nodules along one or more edges of the PCS. Each PCS may optionally include electrical or electronic circuitry on the top and/or bottom surface of the PCS that may be electrical connected with electrical or electronic circuitry on the top and/or bottom surface of another PCS via the respective QP nodules of the PCS'.

In some non-limiting examples or examples, a cooling conduit or pipe may be run through the one or more openings of the 3D substrate assembly or structure and a cooling fluid may be passed through the cooling conduit for cooling the 3D substrate assembly or structure. The cooling conduit may run in a direction generally parallel to faces of the PCS' forming the 3D substrate assembly or structure

In some non-limiting examples or examples, the 3D substrate assembly or structure can be 4-sided cube having only sides, but no top end or bottom end. Other arrangements may include a 3D triangle, a 3D 5-sided substrate assembly or structure, a 3D 6-sided substrate assembly or structure, or a 3D “N”-sided substrate assembly or structure, where N can be any whole number greater than 2.

In some non-limiting examples or examples, one 3D substrate assembly or structure or a number of 3D substrate assemblies or structures connected end-to-end via their respective QP nodules with the opening(s) of the number of the substrate assemblies or structures in series, may include an inner cooling conduit or pipe run through the opening or openings thereof. A cooling medium, e.g., a solid heat transfer means or a cooling fluid, e.g., a cooling liquid or gas, may be run through the inner cooling conduit for cooling the one or more 3D substrate assemblies or structures.

In some non-limiting examples or examples, one 3D substrate assembly or structure or a number of 3D substrate assemblies or structures connected end-to-end via their respective QP nodules with the opening(s) of the number of the substrate assemblies or structures in series can be received in an exterior or outer cooling conduit or pipe that surrounds the one or more 3D substrate assemblies or structures. A cooling medium, e.g., a solid heat transfer means or a cooling fluid, e.g., a cooling liquid or gas, may be run through the exterior cooling conduit for cooling the one or more 3D substrate assemblies or structures. The inner cooling conduit or pipe and the outer cooling conduit or pipe may be used individually or in combination.

In some non-limiting examples or examples, one or a number of the 3D substrate assemblies or structures may be connected in parallel. A number of the parallel connected 3D substrate assemblies or structures may also be connected in series.

In some non-limiting examples or examples, some or all of the PCS' forming each 3D substrate assembly or structure may include optional cooling holes that run therethrough from the top-to-bottom surfaces of the PCS to allow ambient air or gas to flow between an inside and an outside, or vice versa, of the 3D substrate assembly or structure.

In some non-limiting examples or examples, the 3D substrate assembly or structure may be a closed substrate assembly or structure that includes conductive material on all sides forming a Faraday shield, and a connector through at least one substrate for feeding power and/or signals (analog and/or digital) to circuitry disposed on interior and/or exterior surfaces of the closed substrate assembly or structure. An example of such closed substrate assembly or structure may be a cube.

Further non-limiting embodiments or examples are set forth in the following numbered clauses.

Clause 1: A substrate assembly comprises: a plurality of printed circuit substrates (PCS'), wherein each PCS includes a first or top surface and a second or bottom surface spaced from each other and an edge that runs at least partially about a periphery of the PCS between the top surface and the bottom surface; the edge of each PCS includes or defines on a facet or edge surface of said edge a plurality of spaced projections or nodules that extend transverse or normal to said facet or edge surface; and the spaced projections or nodules of each pair of the plurality of PCS' are connected in an interdigitated manner with adjacent or proximate edge surfaces of at least two of the plurality of PCS' positioned at an angle to each other.

Clause 2: The substrate assembly of clause 1, wherein the angle is 90°.

Clause 3: The substrate assembly of clause 1 or 2, wherein at least one spaced projection or nodule of a first PCS of the plurality of PCS' can be shorter in a direction thereof that extends transverse or normal to the facet or edge surface of the first PCS than a subset of the spaced projections or nodules of a second PCS of the plurality of PCS' that can extend transverse or normal to the facet or edge surface of the second PCS.

Clause 4: The substrate assembly of any one of the preceding clauses, wherein each PCS of a subset of the PCS' can include one or more cooling holes that run through the PCS between the top surface and the bottom surface.

Clause 5: The substrate assembly of any one of the preceding clauses, wherein the plurality of PCS' can include a first PCS, a second PCS, and a third PCS connected via the respective spaced projections or nodules of the first PCS, the second PCS, and the third PCS connected in the interdigitated manner to form a three-sided substrate assembly.

Clause 6: The substrate assembly of any one of the preceding clauses, wherein the plurality of PCS' can include a first PCS, a second PCS, a third PCS, and a fourth PCS; wherein the second and fourth PCS' have a first subset of their respective spaced projections or nodules connected in the interdigitated manner with a subset of spaced projections or nodules of the first PCS; and the second and fourth PCS' have a second subset of their respective spaced projections or nodules connected in the interdigitated manner with a subset of spaced projections or nodules of the third PCS to form a four-sided substrate assembly.

Clause 7: The substrate assembly of any one of the preceding clauses, wherein the four-sided substrate assembly can have the form of an open box including four sides, an open top, and an open bottom, wherein the four sides of the open box can define an opening that extends between the open top and the open bottom.

Clause 8: The substrate assembly of any one of the preceding clauses can include a fifth PCS connected via the spaced projections or nodules of the fifth PCS in the interdigitated manner to a first subset of the spaced projections or nodules of the first, second, third, and fourth PCS'; and a sixth PCS connected via the spaced projections or nodules of the sixth PCS in the interdigitated manner to a second subset of the spaced projections or nodules of the first, second, third, and fourth PCS' to form a six-sided substrate assembly, e.g., a cube.

Clause 9: The substrate assembly of any one of the preceding clauses can further comprise a pair of the four-sided substrate assemblies in the form of open boxes connected together via a subset of the spaced projections or nodules of the PCS' comprising the pair of the four-sided substrate assemblies with the openings of the pair of the four-sided substrate assemblies positioned in series to form an elongated box-like structure.

Clause 10: The substrate assembly of any one of the preceding clauses can include further including an internal conduit, tube, or pipe positioned through the openings of the pair of the four-sided substrate assemblies positioned in series.

Clause 11: The substrate assembly of any one of the preceding clauses can include thermal packing between the internal conduit, tube, or pipe and the PCS' forming the pair of the four-sided substrate assemblies.

Clause 12: The substrate assembly of any one of the preceding clauses can further include an external conduit, tube, or pipe surrounding the sides of the pair of four-sided substrate assemblies.

Clause 13: The substrate assembly of any one of the preceding clauses can include thermal packing between the external conduit, tube, or pipe and the PCS' forming the pair of the four-sided substrate assemblies.

Clause 14: The substrate assembly of any one of the preceding clauses can include: a first pair of the four-sided substrate assemblies in the form of open boxes connected together via a subset of the spaced projections or nodules of the PCS' comprising the first pair of the four-sided substrate assemblies with the openings of the first pair of the four-sided substrate assemblies positioned in series; and a second pair of the four-sided substrate assemblies in the form of open boxes connected together via a subset of the spaced projections or nodules of the PCS' comprising the second pair of the four-sided substrate assemblies with the openings of the second pair of the four-sided substrate assemblies positioned in series; wherein the first and second pairs of the four-sided substrate assemblies are connected side-by-side with the openings of the first pair of the four-sided substrate assemblies positioned in series running in the same direction as the openings of the second pair of the four-sided substrate assemblies positioned in series.

Clause 15: The substrate assembly of any one of the preceding clauses, wherein the plurality of PCS' can include: a first PCS and a second PCS connected in a plane or straight line to each other via the respective spaced projections or nodules of the first PCS and the second PCS connected in the interdigitated manner; and a third PCS connected at a transverse or right angle to the first PCS and the second PCS, wherein the spaced projections or nodules of the third PCS are connected to the interdigitated connection of the respective spaced projections or nodules of the first PCS and the second PCS to form a T-shaped or substantially T-shaped substrate assembly

Clause 16: The substrate assembly of any one of the preceding clauses, wherein the spaced projections or nodules of the first PCS and the second PCS connected in the interdigitated manner can include at least one of the spaced projections or nodules of the first PCS is shorter than the spaced projections or nodules of the second PCS disposed on opposite sides of the at least one spaced projection or nodule of the first PCS whereupon a gap exists between a distal end of the at least one spaced projection or nodule of the first PCS and the side surface of the second PCS, and at least one of the spaced projections or nodules of the third PCS is inserted in this gap.

### BRIEF DESCRIPTION OF THE DRAWINGS

These and other features of the present invention will become more apparent from the following description wherein reference is made to the appended drawings wherein:

FIGS. 1A-1B are exploded and assembled perspective views of three PCS' assembled together to form a three-sided or half-box substrate assembly according to the principles of the present invention;

FIG. 2 is an assembled perspective view of four PCS' assembled together to form a four-sided or box-shaped substrate assembly with an open top end, an open bottom end, and with an opening that extends between the open top end and the open bottom end according to the principles of the present invention;

FIG. 3A is an assembled plan view of the bottom surfaces of two PCS' assembled together in a plane or straight line to each other according to the principles of the present invention;

FIG. 3B is a perspective view of a third PCS connected transverse or perpendicular to the top surfaces of the two PCS' shown in FIG. 3A according to the principles of the present invention;

FIG. 4A is an exploded perspective view of a pair of the box-shaped substrate assemblies shown in FIG. 2 positioned with the open ends thereof in spaced facing relation according to the principles of the present invention;

FIGS. 4B-4D are assembled perspective view of the pair of the box-shaped substrate assemblies shown in FIG. 4A with the openings that extend through each box-shaped substrate assembly positioned in series according to the principles of the present invention;

FIG. 5 is an assembled perspective view of box-shaped substrate assembly of FIG. 2 including another PCS covering the top end and another PCS covering the bottom end to form a six-sided substrate assembly and including a connector on one surface of one the PCS' of the six-sided substrate assembly according to the principles of the present invention;

FIG. 6 is a perspective view of the assembled pair of the box-shaped substrate assemblies shown in FIG. 4B-4D including an internal pipe, tube, or conduit positioned through the openings of said pair of the box-shaped substrate assemblies, with optional thermal packing between the internal pipe, tube, or conduit and the PCS' of the box-shaped substrate assembly according to the principles of the present invention;

FIG. 7 is a perspective view of the assembled pair of the box-shaped substrate assemblies shown in FIG. 4B-4D including an external pipe, tube, or conduit positioned surrounding the sides of said pair of the box-shaped substrate assemblies, with optional thermal packing between the external pipe, tube, or conduit and the PCS' of the box-shaped substrate assembly, and with an optional internal pipe, tube, or conduit positioned through the openings of said pair of the box-shaped substrate assemblies as shown in FIG. 6, and with optional thermal packing between the internal pipe, tube, or conduit and the PCS' of the box-shaped substrate assembly according to the principles of the present invention;

FIG. 8 is an assembled perspective view of three lines or lanes of the box-shaped substrate assemblies, like the box-shaped substrate assemblies shown in FIG. 2, with each line or lane including three box-shaped substrate assemblies connected end-to-end, with the openings thereof that extend between each open top end and each open bottom end in series according to the principles of the present invention according to the principles of the present invention;

FIG. 9 is an assembled perspective view of two of the pair of the box-shaped substrate assemblies shown in FIGS. 4B-4D connected end-to-end with the openings thereof that extend between each open top end and each open bottom end in series and including optional cooling holes in a subset of the PCS' thereof according to the principles of the present invention; and

FIG. 10 is an assembled perspective view of three lines or lanes of the box-shaped substrate assemblies shown in FIG. 8 further including optional cooling holes in a subset of the PCS' thereof according to the principles of the present invention.

### DETAILED DESCRIPTION OF THE INVENTION

The following examples will be described with reference to the accompanying figures, where like reference numbers correspond to like or functionally equivalent elements. Persons of ordinary skill in the art will realize that the following examples are illustrative only and not in any way limiting. Other examples will readily suggest themselves to such skilled persons.

For purposes of the description hereinafter, the terms “end,” “upper,” “lower,” “right,” “left,” “vertical,” “horizontal,” “top,” “bottom,” “lateral,” “longitudinal,” and derivatives thereof shall relate to the example(s) as oriented in the drawing figures or as understood in the art. However, it is to be understood that the example(s) may assume various alternative variations and step sequences, except where expressly specified to the contrary. It is also to be understood that the specific example(s) illustrated in the attached drawings, and described in the following specification, are simply exemplary examples or aspects of the invention. Hence, the specific examples or aspects disclosed herein are not to be construed in a limiting sense.

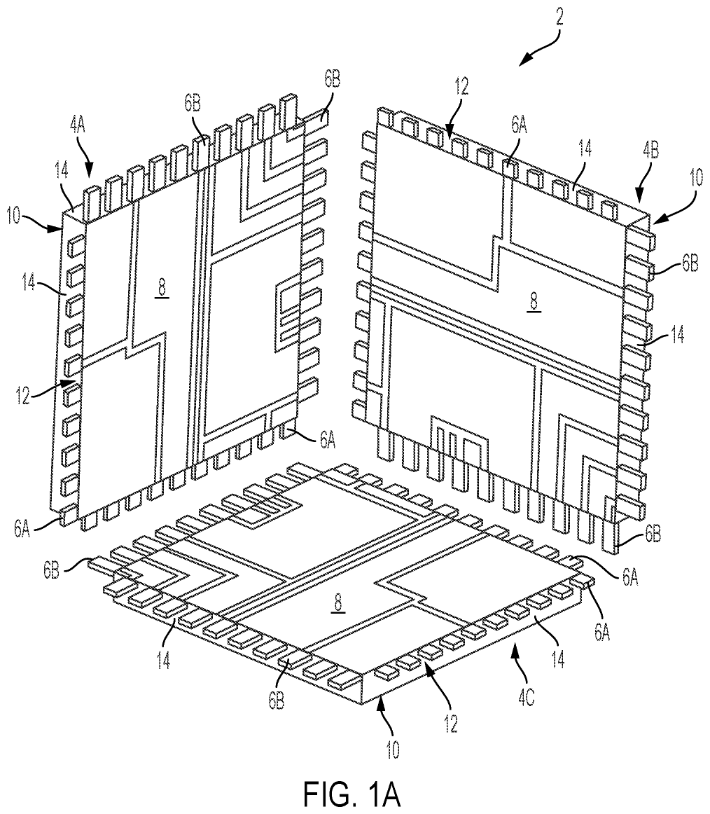

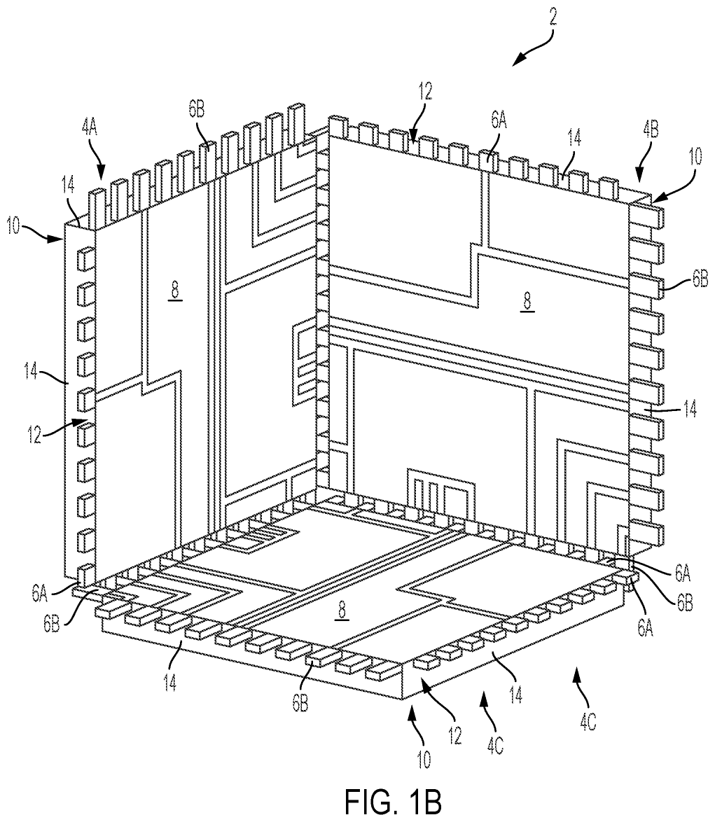

With reference to FIGS. 1A-1B, in some non-limiting embodiments or examples, a 3D substrate assembly or structure 2 in accordance with the principles of the present invention can include three printed circuit substrates (PCS') 4, namely, PCS 4A, PCS 4B, and PCS 4C, connected together via QP nodules 6, also referred to herein as projections or nodules, to form a three-sided or half-box substrate assembly or structure.

Herein, each PCS 4 can be an integrated circuit chip (IC) including circuitry formed thereon in a manner known in the art or a printed circuit (or wiring) board (PCB) having circuitry (or no circuitry) formed on and/or mounted to one or both surfaces 8 and/or 10 of the PCB in a manner known in the art. Examples of the circuitry that may be formed on and/or mounted to one or more surfaces 8 and/or 10 of a PCS 4 in the nature of a PCB may include one or more of: (1) one or more conductive traces; (2) one or more passive components, such as resistors, capacitors, and inductors; (3) one or more active components, such as transistors; and/or (4) one or more ICs. However, this listing of example circuitry is not to be construed in a limiting sense inasmuch as it is envisioned that other circuitry, now known or hereinafter developed, may also or alternatively be formed on and/or mounted to one or more surfaces of a PCS 4 in the nature of a PCB. Moreover, for any 3D substrate assembly or structure 2 described herein, each PCS 4 and the circuitry and/or function thereof may be different or the same as the circuitry and/or function of any other PCS 4 of said 3D substrate assembly or structure 2. Accordingly, the illustration and/or description of any PCS 4 herein is not to be construed in a limiting sense.

In some non-limiting embodiments or examples, one or more PCS' 4, e.g., in the nature of a PCB, having no circuitry formed on and/or mounted to one or both surfaces of the PCS 4 may be used as a supporting member to form a 3D substrate assembly or structure 2 that includes one or more PCS' other connected together in accordance with the principles of the present invention that may include circuitry on one or more surfaces thereof.

In an example, each PCS 4 includes a first or top surface 8 and a second or bottom surface 10 spaced from each other and an edge 12 that runs at least partially about a periphery of the PCS 4 between the top surface 8 and the bottom surface 10. Herein, when used in connection with a PCS 4 being described herein, the terms “top surface” and “bottom surface” are used strictly to readily distinguish the opposing surfaces of the PCS 4 and, therefore, these terms are not to be construed in a limiting sense.

The edge 12 of each PCS 4 includes or defines on a facet or edge surface 14 of said edge 12 a plurality of spaced nodules 6 that extend transverse or normal to said facet or edge surface 14. As shown in FIG. 1B, the spaced nodules of adjacent or proximate edge surfaces of each pair PCS' 4 can be connected in an interdigitated manner. In an example, each pair PCS' 4 can be connected at an angle to each other. In some non-limiting embodiments or examples, each pair PCS' 4 can be connected in an interdigitated manner with adjacent or proximate edge surfaces of said pair of PCS' positioned at an angle of 90° to each other. In other non-limiting embodiments or examples, the spaced nodules of each pair the plurality of PCS' can be connected in an interdigitated manner with adjacent or proximate edge surfaces of said pair of PCS' positioned at an angle between 30° and 135°, inclusive, to each other.

In some non-limiting embodiments or examples, each of a subset of the PCS' 4 can include a first subset of nodules 6A (including a single nodule 6A) that extend(s) shorter in a (length) direction transverse or normal to the edge surface 14 of said PCS than a second subset of nodules 6B (including a single nodule 6B) of said PCS. However, this is not to be construed in a limiting sense since it is envisioned that all of the nodules 6 of one or more of the PCS' 4 can have or can be the same length or substantially the same length (as dictated by the process used to manufacture the PCS 4). In another example, all of the nodules 6 of one PCS, e.g., PCS 4A, can be of a first length, all of the nodules 6 of a second PCS, e.g., PCS 4B, can all be of second, same or different length, as the nodules 6 of PCS 4A, and all of the nodules 6 of a third PCS, e.g., PCS 4C, can all be of third, same or different length, as the nodules 6 of PCS' 4A and/or 4B. In other words, the nodules 6 of each PCS 4 can have any suitable and/or desirable length deemed suitable and/or desirable, e.g., for a particular application.

As shown in FIG. 1B, in some non-limiting embodiments or examples, shorter length nodules 6A of one PCS, e.g., PCS 4C, can be connected in an interdigitated manner with longer length nodules 6B of another PCS, e.g., PCS 4B. However, this is not to be construed in a limiting sense since it is envisioned that nodules 6 of any length of one PCS 4 can be connected in an interdigitated manner with nodules 6 of any length of another PCS 4.

At a suitable time, solder or adhesive may be used to secure or affix together nodules 6 of any number of PCS' 4 described herein connected in an interdigitated manner.

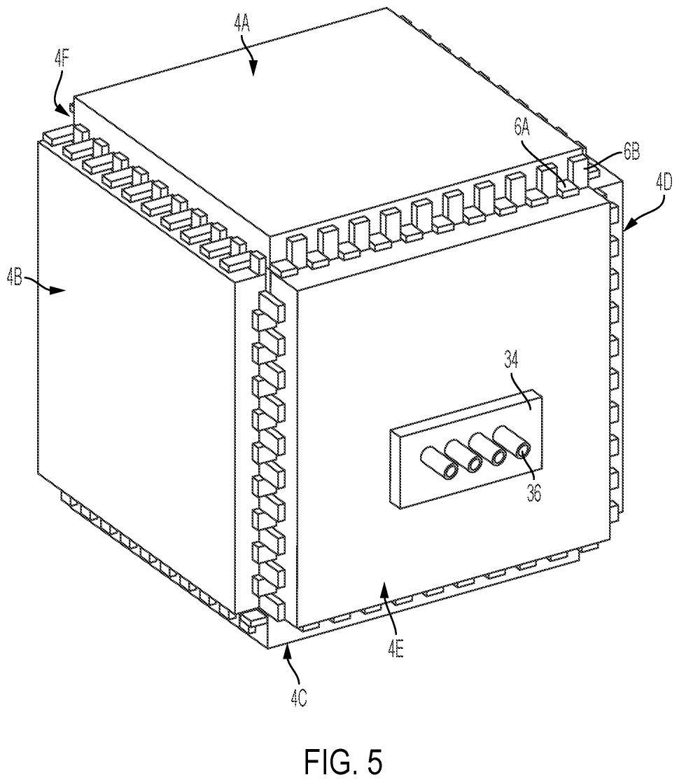

In some non-limiting embodiments or examples, two of the three-sided or half-box shaped substrate assemblies or structures shown in FIG. 1B may be assembled together, with their respective spaced nodules 6 connected in an interdigitated manner to form a six-sided or box shaped substrate shown, for example, in FIG. 5.

Nodules 6 described herein are used to mechanically connect and, preferably, also electrically connect, two or more PCS's 4. To this end, nodules 6 may include or be formed from electrically conductive material that enables nodules 6 to electrically connect two or more PCS' s 4.

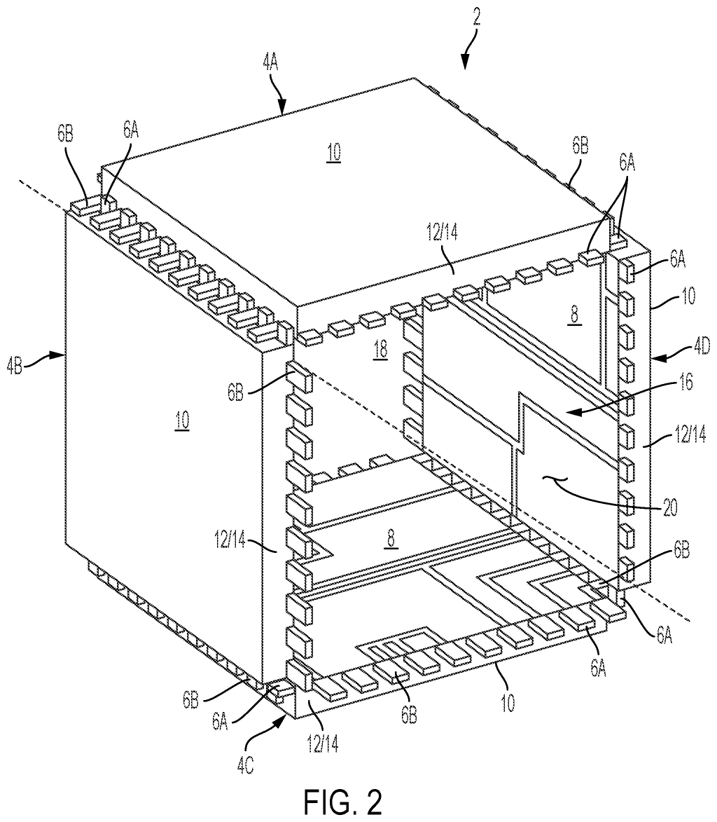

With reference to FIG. 2, in some non-limiting embodiments or examples, a 3D substrate assembly or structure 2 in accordance with the principles of the present invention can include four PCS' 4, namely, PCS 4A, PCS 4B, PCS 4C, and PCS 4D connected together via nodules 6 connected in an interdigitated manner to form the four sides of a four-sided or box-shaped substrate assembly or structure having an open top end 16, an open bottom end 18, and with an opening 20, defined by the top sides 8 (or bottom sides 10) of the four PCS' 4, that extends between the open top end 16 and the open bottom end 18.

In FIG. 2, shorter length nodules 6A of one PCS, e.g., PCS 4A, can be connected in an interdigitated manner with longer length nodules 6B of another PCS, e.g., PCS 4B. However, this is not to be construed in a limiting sense since it is envisioned that nodules 6 of any length of one PCS 4 can be connected in an interdigitated manner with nodules 6 of any length of another PCS 4.

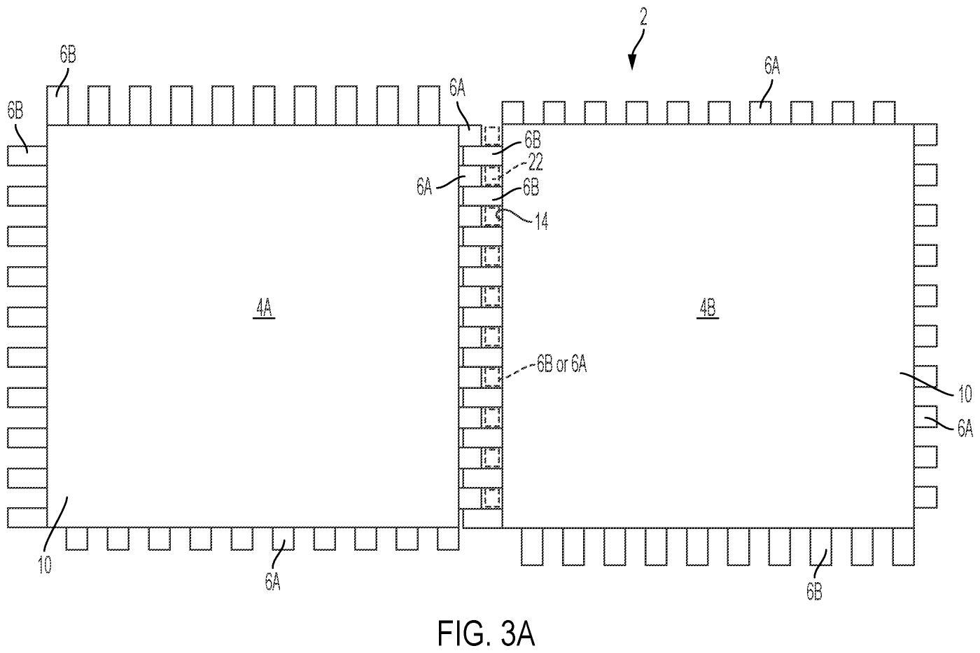

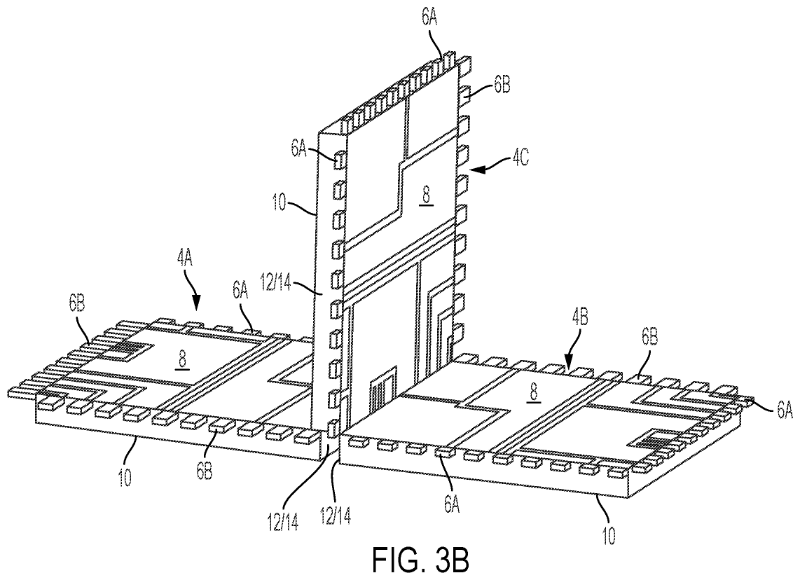

With reference to FIG. 3A-3B, in some non-limiting embodiments or examples, a 3D substrate assembly or structure 2 in accordance with the principles of the present invention can include two PCS' 4, namely, PCS 4A and PCS 4B, connected together in a plane or straight line to each other via nodules 6 of PCS 4A and PCS 4B connected in an interdigitated manner. FIG. 3A is a plan view of the bottom surfaces 10 of PCS' 4A and 4B.

In an example, the nodules 6 of PCS 4A and PCS 4B connected in an interdigitated manner can include short length nodules 6A of PCS 4A connected in an interdigitated manner with longer length nodules 6B of PCS 4B to form gaps or spaces 22 between (1) pairs of adjacent or proximate nodules 6B of PCS 4B, (2) a distal or free end of the nodules 6A of PCS 4A between each said pair of adjacent or proximate pairs of nodules 6B of PCS 4B, and (3) the end surface 14 of the edge 12 of PCS 4B that faces the distal or free end of the nodules 6A of PCS 4A.

As shown in FIG. 3B, a third PCS 4C can be connected transverse or perpendicular to the top surfaces 8 of the PCS' 4A-4B assembled shown in FIG. 3A, with nodules 6 of third PCS 4C inserted (as shown in phantom in FIG. 3A) into the spaces 22 formed by the interdigitated connection of the short length nodules 6A of PCS 4A connected the longer length nodules 6B of PCS 4B in the manner shown in FIG. 3A. In the example shown in phantom in FIG. 3A, nodules 6B (or nodules 6A) of third PCS 4C can be inserted into the spaces 22 to form the T-shaped substrate assembly or structure shown in FIG. 3B.

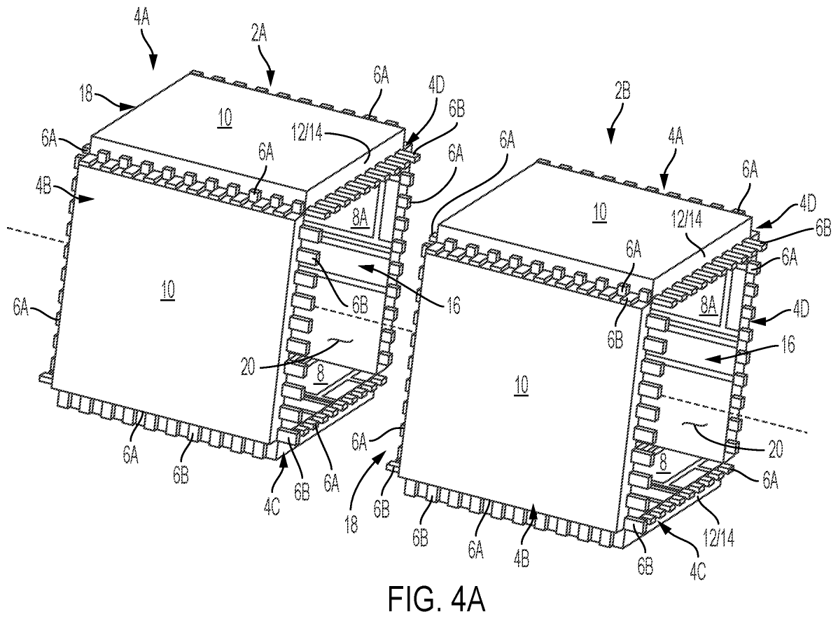

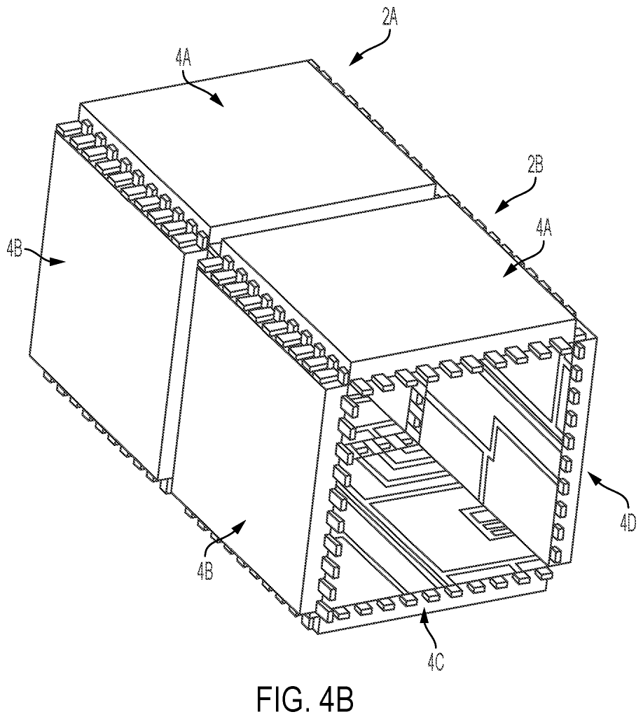

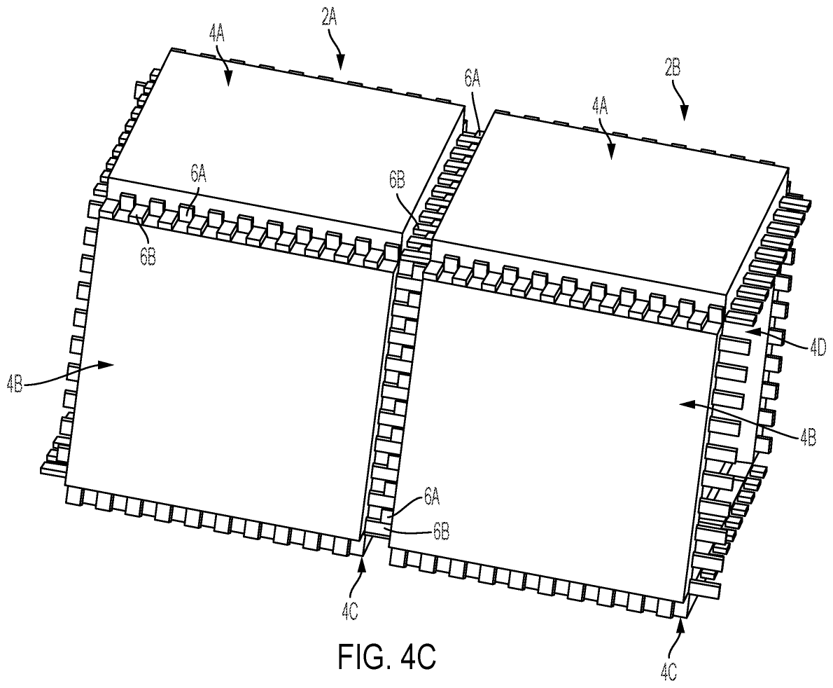

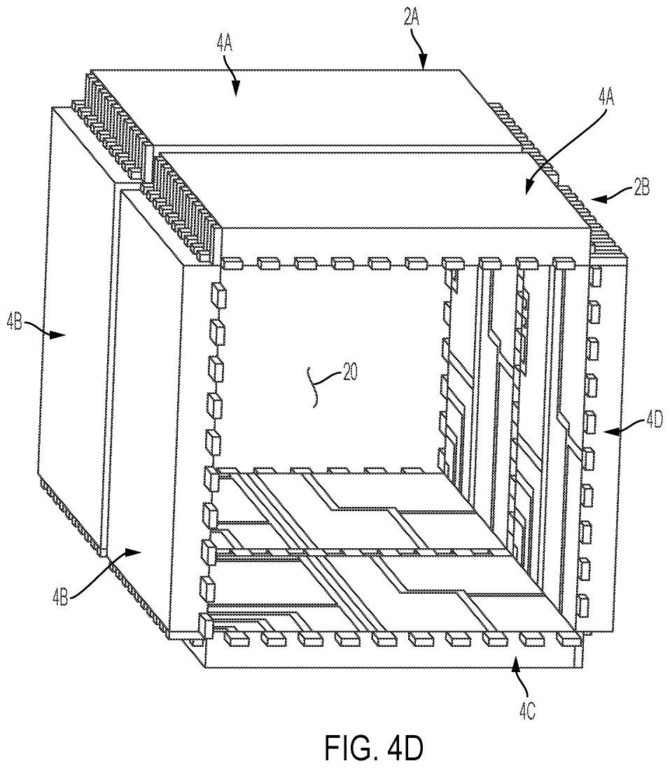

With reference to FIGS. 4A-4D, in some non-limiting embodiments or examples, a 3D substrate assembly or structure in accordance with the principles of the present invention can include two or more four-sided or box-shaped substrate assemblies 2A and 2B of the type shown in FIG. 2 connected end-to-end via nodules 6 PCS' of connected in an interdigitated manner with the openings 20 through the two or more four-sided or box-shaped substrate assemblies 2A and 2B positioned in series.

In some non-limiting embodiments or examples, and as shown, for example, in FIG. 4C, the interdigitated connected nodules 6 of box-shaped substrate assemblies 2A and 2B for can include longer length nodules 6B of one PCS, e.g., PCS 4B, of box-shaped substrate assembly or structure 2A, connected in an interdigitated manner with shorter length nodules 6A of one PCS, e.g., PCS 4B, of box-shaped substrate assembly or structure 2B.

However, in general, this is not to be construed in a limiting sense since it is envisioned that any length nodules of one PCS can be connected in an interdigitated manner with any length nodules of another PCS. Moreover, in general, nodules 6 of a pair of PCS' may be connected together in an interdigitated manner at a right angle, or at a straight angle, or at an angle between a right angle and a straight angle, i.e., an acute angle, or at an angle greater than a right angle, i.e., an obtuse angle.

With reference to FIG. 5, in some non-limiting embodiments or examples, another 3D substrate assembly or structure in accordance with the principles of the present invention can include the four-sided or box-shaped substrate assembly or structure of the type shown in FIG. 2 including the four side PCS' 4A-4D, and can further include a top cover PCS 4E and a bottom cover PCS 4F to form an enclosed box-shaped or cube-shaped substrate assembly or structure shown in FIG. 5.

In some non-limiting embodiments or examples, a connector 34 may be mounted to an exterior facing surface, i.e., the top surface 8 or the bottom surface 10, of one of the PCS' 4, e.g., PCS 4E in FIG. 5. Contacts 36 of the connector 34 may connect, in a manner known in the art, to circuitry of PCS 4E, in the nature of an IC or in the nature of PCB, on one or both surfaces of PCS 4E. This circuitry of PCS 4E, in-turn, may be connected to circuitry (if provided) of one or more of the other PCS' 4 of the enclosed box-shaped or cube-shaped substrate assembly or structure shown in FIG. 5 via the nodules 6 of the PCS' 4 forming said enclosed box-shaped or cube-shaped substrate assembly or structure. The contacts 36 of the connector 34 may be used for feeding power and/or signals (analog and/or digital) to circuitry of one or more the PCS'4 forming the enclosed box-shaped or cube-shaped substrate assembly or structure. The use of multiple connectors 34 on one more PCS' 4 forming the enclosed box-shaped or cube-shaped substrate assembly or structure is also envisioned.

Herein, PCS' 4 are illustrated having circuitry on one surface, e.g., the first or top surface 8, and no circuitry on the other surface, e.g., the second or bottom surface 10. However, this is not to be construed in a limiting sense since it is envisioned that circuitry may be included on one or both or no surfaces of one or more of the PCS' 4 forming the various 3D substrate assemblies or structures described herein.

In the enclosed box-shaped or cube-shaped substrate assembly or structure shown in FIG. 5 (and in all of the other examples described herein), each pair of PCS' may be connected together in an interdigitated manner via nodules 6 in any of the manners discussed above in connection with the examples of FIGS. 1A-4D. In an example, each pair of PCS' may include one PCS including short length nodules 6A connected in an interdigitated manner with longer length nodules 6B of another PCS of said pair of PCS'. In another example, short length nodules 6A of one PCS of the pair of PCS' may be connected in an interdigitated manner with short length nodules 6A of another PCS of said pair of PCS'. In yet another example, longer length nodules 6B of one PCS of the pair of PCS' may be connected in an interdigitated manner with longer length nodules 6B of another PCS of said pair of PCS'.

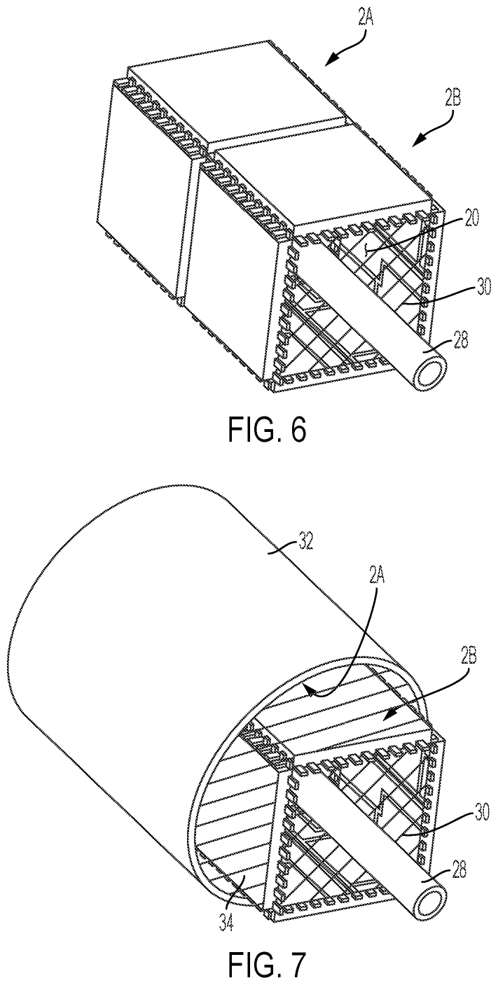

With reference to FIG. 6, in some non-limiting embodiments or examples, a 3D substrate assembly or structure in accordance with the principles of the present invention can include two or more of the four-sided or box-shaped substrate assemblies 2A and 2B of the type shown in FIG. 2 connected end-to-end via the interdigitated nodules 6 of said substrate assemblies 2A and 2B as shown, for example, in FIG. 4B. An inner or internal conduit, tube, or pipe 28 may extend through or be projected though the serial arranged openings 20 of the two or more end-to-end connected substrate assemblies.

In some non-limiting embodiments or examples, inner pipe 28 may be used to conduct a fluid, e.g., water or other heat conductive fluid, that may be used, in combination with inner pipe 28, for conducting heat from circuitry of, formed on, and/or mounted to one or more surfaces of the PCS' 4 forming the substrate assemblies 2A and 2B.

In some non-limiting embodiments or examples, optional thermal packing material 30 may be disposed between an outer surface of inner pipe 28 and the surfaces of the PCS' 4 forming the substrate assemblies 2A and 2B that face the outer surface of inner pipe 28 as an aid for conducting heat generated by circuitry formed on and/or mounted to one or more surfaces of the PCS' 4 forming the substrate assemblies 2A and 2B to the fluid flowing through inner pipe 28. Non-limiting examples of thermal packing material 30 may include thermal packing grease or epoxy.

In some non-limiting embodiments or examples, a 3D substrate assembly or structure in accordance with the principles of the present invention can include a single four-sided or box-shaped substrate assembly 2 including inner pipe 28 extending or projected though the opening 20 of said box-shaped substrate assembly 2 with thermal packing material 30 optionally disposed between the outer surface of inner pipe 28 and the surfaces of the PCS' 4 forming said single substrate assemblies 2A and 2B that face the outer surface of inner pipe 28.

With reference to FIG. 7 and with ongoing reference to FIG. 6, in some non-limiting embodiments or examples, a 3D substrate assembly or structure in accordance with the principles of the present invention may include an outer or external conduit, tube, or pipe 32 surrounding at least portions, preferably all, of two or more end-to-end connected substrate assemblies 2A and 2B, or some portion thereof.

In some non-limiting embodiments or examples, outer pipe 32 may be used to conduct a cooling fluid, e.g. a cooling gas or liquid, e.g., an inert gas or liquid, that may contact the surfaces of substrate assemblies 2A and 2B without adversely affecting the operation of circuitry formed on and/or mounted to one or more surfaces of one or more of the PCS' 4 forming the substrate assemblies 2A and 2B.

In another example, thermal packing material 34 may also or alternatively be disposed between an inner surface of outer pipe 28 and the outward facing surfaces of the PCS' 4 forming the substrate assemblies 2A and 2B that face outer pipe 32 as an aid for conducting heat generated by circuitry formed on and/or mounted to one or more surfaces of the PCS' 4 forming the substrate assemblies 2A and 2B to outer pipe 32. Non-limiting examples of thermal packing material 34 may include thermal packing grease or epoxy.

In FIGS. 6 and 7, the length(s) of one or both of inner pipe 28 and outer pipe 32 are strictly for the purpose of illustration and is/are not to be construed in a limiting sense since it is envisioned that one or both pipes 28 and/or 32 may have any length deemed suitable and/or desirable for a particular application.

In the example shown in FIG. 7, inner pipe 28 may be omitted and outer pipe 32 may be used without inner pipe 28. Moreover, in the example shown in FIG. 7, outer pipe 32 may be used with a single substrate assembly 2, with or without inner pipe 28.

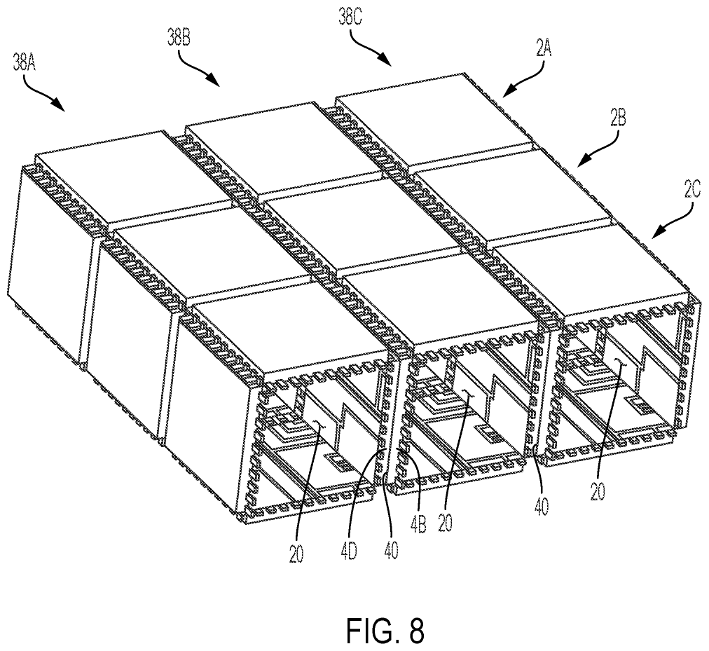

With reference to FIG. 8, in some non-limiting embodiments or examples, a 3D substrate assembly or structure in accordance with the principles of the present invention may include plural lines or lanes 38 of the box-shaped substrate assemblies 2 shown in FIG. 2. Each line or lane 38 may include plural box-shaped substrate assemblies 2 connected end-to-end, with their respective openings 20 in series, via the respective nodules 6 thereof, for example, in the manner described above in connection with FIG. 4A-4D for a pair of box-shaped substrate assemblies.

The example 3D substrate assembly or structure shown in FIG. 8, includes three lines or lanes 38A-38C of box-shaped substrate assemblies, with each line or lane including three box-shaped substrate assemblies 2A, 2B, and 2C. However, the number of lines or lanes 38 and the number of box-shaped substrate assemblies 2 included in each line or lane 38 is not to be construed in a limiting sense since it is envisioned that the 3D substrate assembly or structure shown in FIG. 8 may include any number of lines or lanes 38 and each line or lane 38 may include any number of box-shaped substrate assemblies 2. Moreover, different lines or lanes 38 may include different numbers of box-shaped substrate assemblies 2. For example, line or lane 38A may include one or two substrate assemblies 2, line or lane 38B may include three substrate assemblies 2, and line or lane 38C may include one or two substrate assemblies 2. However, is not to be construed in a limiting sense.

In an example, opposing surfaces of PCS' 4 in adjacent or proximate lines or lanes 38, e.g., lines or lanes 38A and 38B and lines or lanes 38B and 38C, may be joined or connected together via solder or a suitable adhesive 40. For example, as shown in FIG. 8, surfaces 4D and 4B of box-shaped substrate assembly 2C in lines or lanes 38A and 38B may be joined or connected together via solder or adhesive 40.

One or both of said opposing surfaces joined or connected together via a solder or adhesive 40 may or may not include circuitry thereon as may be deemed suitable and/or desirable for a particular application. For example, in the example shown in FIG. 8, one or both of surfaces 4D and 4B of box-shaped substrate assemblies 2C in lines or lanes 38A and 38B joined or connected together via solder or suitable adhesive 40 may or may not include circuitry thereon.

Also or alternatively to the use of solder or adhesive 40, opposing surfaces of one or more PCS' 4 in adjacent or proximate lines or lanes 38 may be connected together via nodules 6 connected together in an interdigitated manner. In an example, the lengths of nodules 6 of PCS' 4 in adjacent or proximate lines or lanes 38 may be formed sufficiently long whereupon the nodules 6 of said PCS' 4 in said adjacent or proximate lines or lanes 38 may be connected together in an interdigitated manner. For example, nodules 6 of one or more PCS' 4D of substrate assemblies 2A-2C of line or lane 38A may be connected in in an interdigitated manner with nodules of one or more PCS' 4B of substrate assemblies 2A-2C of line or lane 38B. However, this is not to be construed in the limiting sense.

One non-limiting example application of the 3D substrate assembly or structure shown in FIG. 8 may include line or lane 38B including high power circuitry and lines or lanes 38A and 38C including small signal/lower power circuitry. However, this example application is not to be construed in a limiting sense.

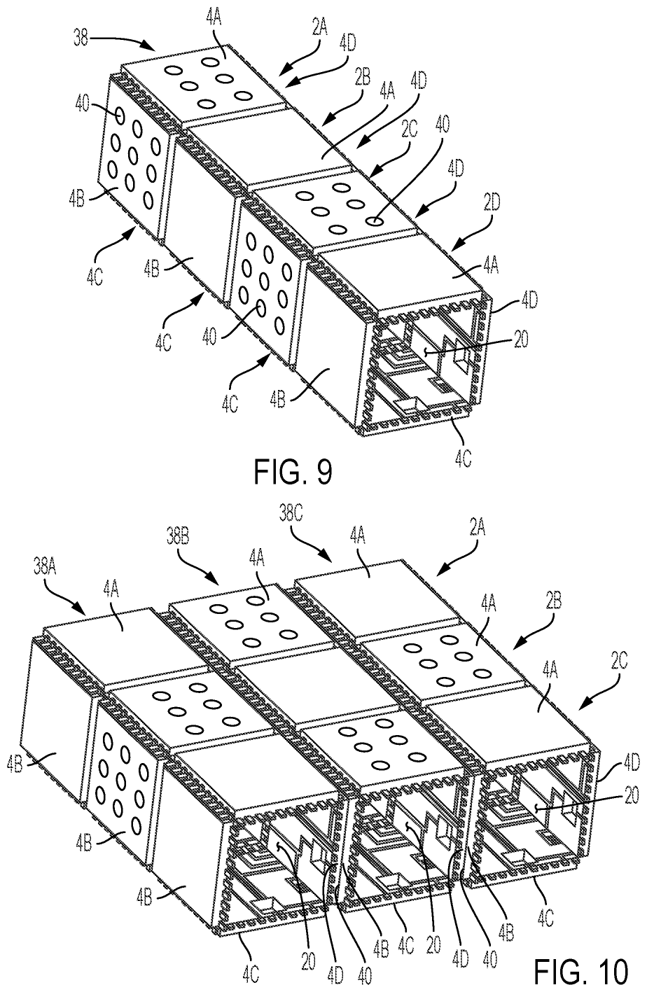

With reference to FIG. 9, in some non-limiting embodiments or examples, a 3D substrate assembly or structure in accordance with the principles of the present invention may include a single line or lane 38 of the box-shaped substrate assemblies 2 shown in FIG. 2 connected end-to-end via the respective nodules 6 thereof, for example, in the manner described above in connection with FIG. 4A-4D for a pair of box-shaped substrate assemblies. The example 3D substrate assembly or structure 38 shown in FIG. 9, includes four box-shaped substrate assemblies 2A, 2B, 2C, and 2D connected end-to-end with their openings 20 in series. However, this is not to be construed in a limiting sense since it is envisioned that the single line or lane 38 of the box-shaped substrate assemblies 2 shown in FIG. 9 may include any number of box-shaped substrate assemblies 2 connected end-to-end with their openings 20 in series.

In some non-limiting embodiments or examples, a subset of one or all the PCS' 4 of the box-shaped substrate assemblies 2 shown in FIG. 9 may include one or more holes 42 therethrough. In an example, box-shaped substrate assemblies 2A and 2C may include one or more holes 42 in some or all of the PCS' 4 thereof. In FIG. 9, each box-shaped substrate assembly 2A and 2C is shown having multiple holes 42 in PCS' 4A and 4B thereof. However, it is envisioned that box-shaped substrate assemblies 2A and 2C may also include one or more holes in PCS' 4C and 4D thereof. Moreover, the number and location of the holes 42 in the PCS' 4 shown in FIG. 9 is not to be construed in a limiting sense since the number and location(s) of the holes 42 in any PCS' 4 may selected by one skilled in the art for an application. For example, one or more holes 42 may be included in one or more PCS' 4 of one or more box-shaped substrate assembly 2 shown in FIG. 9. Accordingly, the holes 42 shown in PCS' 4A-4B of box-shaped substrate assemblies 2A and 2C are not to be construed in a limiting sense.

In some non-limiting embodiments or examples, the holes 42 may be used to conduct cooling air or gas therethrough to cool circuitry of 3D substrate assembly or structure shown in FIG. 9. Also or alternatively, the holes 42 may be used to conduct electric and/or magnetic, e.g., electromagnetic (EM), signals to circuitry of 3D substrate assembly or structure shown in FIG. 9.

With reference to FIG. 10, in some non-limiting embodiments or examples, a 3D substrate assembly or structure in accordance with the principles of the present invention may include the plural lines or lanes 38 of box-shaped substrate assemblies 2 shown in FIG. 8 including one or more holes 42 in some or all of the PCS' 4 thereof as shown, for example, in FIG. 9. In FIG. 10, box-shaped substrate assemblies 2A and 2C in line or lane 38B are shown having multiple holes 42 in PCS' 4A thereof. However, it is envisioned that box-shaped substrate assemblies 2A and 2C in line or lane 38B may also include one or more holes in PCS' 4C thereof.

Moreover, box-shaped substrate assembly 2B in line or lane 38A is shown having multiple holes 42 in PCS' 4A and 4B thereof. However, it is envisioned that box-shaped substrate assembly 2B in line or lane 38A may also include one or more holes in PCS 4C thereof. Also, box-shaped substrate assembly 2B in line or lane 38C is shown having multiple holes 42 in PCS 4A thereof. However, it is envisioned that box-shaped substrate assembly 2B in line or lane 38A may also include one or more holes in one or more of PCS' 4B and 4C thereof.

In another example, opposing surfaces of PCS' 4 (e.g., surfaces 4D and 4B of box-shaped substrate assembly 2C in lines or lanes 38A and 38B) in adjacent or proximate lines or lanes 38, e.g., lines or lanes 38A and 38B and lines or lanes 38B and 38C, joined or connected together via solder or a suitable adhesive 40 and/or via nodules 6 connected together in an interdigitated manner may include holes 40 therethrough that are at least partially in alignment to facilitate the lateral conduction of cooling air or gas and/or EM signals to circuitry of the box-shaped substrate assemblies 2 in line or lane 38B.

The number and location of the holes 42 in the PCS' 4 shown in FIG. 10 is not to be construed in a limiting sense since the number and location(s) of the holes 42 in any PCS' 4 may selected by one skilled in the art for an application. For example, one or more holes 42 may be included in one or more PCS' 4 of one or more box-shaped substrate assemblies 2 of one or more lines or lanes 38 shown in FIG. 10. Accordingly, the holes 42 shown in the PCS' 4 of box-shaped substrate assemblies 2 of the lines or lanes 38 shown in FIG. 10 are not to be construed in a limiting sense.

In some non-limiting embodiments or examples, any surface 8 and/or 10 of any of the PCS' 4 described herein may optionally include a whole or partial layer of conductive material that forms at least a partial Faraday shield to EM signals. In an example, one or all of the bottom (or outward facing) surfaces 10 of the four sides of the four-sided or box-shaped substrate assembly or structure shown in FIG. 2 may include a whole or partial layer of conductive material that forms at least a partial Faraday shield to EM signals. However, this is not to be construed in a limiting sense.

Finally, the shapes of the various 3D substrate assemblies or structures shown and described herein, e.g., the four-sided or box-shaped substrate assembly or structure shown in FIG. 2, are not to be construed in a limiting sense since 3D substrate assemblies or structures having other shapes are is envisioned. For example, a 3D substrate assembly or structure is envisioned that has three connected sides forming a three-sided or triangle-shaped 3D substrate assembly having an opening extending therethrough, like opening 20 in the four-sided or box-shaped substrate assembly or structure shown in FIG. 2, having angles between adjacent or proximate surfaces 8 and/or 10, or between adjacent or proximate edge surfaces 14, between, for example, 90° and 135°, preferably 130°. In other examples, also envisioned are 3D substrate assemblies or structures having openings extending therethrough, like opening 20 in the four-sided or box-shaped substrate assembly or structure shown in FIG. 2, that include: five sides (a pentagon shape); six sides (a hexagon shape); seven sides (a heptagon shape); eight sides (an octagon shape); nine sides (a nonagon shape); or ten sides (a decagon shape) having angles between adjacent or proximate surfaces 8 and/or 10, or between adjacent or proximate edge surfaces 14, between 30° and 90° to each other.

Although the invention has been described in detail for the purpose of illustration based on what is currently considered to be the most practical and preferred embodiments or examples, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

The invention claimed is:

1. A substrate assembly comprising;
a plurality of printed circuit substrates (PCS'), wherein:
each PCS includes a first or top surface and a second or bottom surface spaced from each other and an edge that runs at least partially about a periphery of the PCS between the top surface and the bottom surface;
the edge of each PCS includes or defines on a facet or edge surface of said edge a plurality of spaced projections or nodules that extend transverse or normal to said facet or edge surface; and
the spaced projections or nodules of each pair of the plurality of PCS' are connected in an interdigitated manner with adjacent or proximate edge surfaces of at least two of the plurality of PCS' positioned at an angle to each other.

2. The substrate assembly of claim 1, wherein the angle is 90°.

3. The substrate assembly of claim 1, wherein a first subset of the spaced projections or nodules of at least one PCS of the plurality of PCS' is shorter in a direction thereof that extends transverse or normal to the facet or edge surface of the first PCS than a second subset of the spaced projections or nodules of said at least one PCS.

4. The substrate assembly of claim 1, wherein each PCS of a subset of the plurality of PCS' include one or more cooling holes that run through the PCS between the top surface and the bottom surface.

5. The substrate assembly of claim 1, wherein the plurality of PCS' include a first PCS, a second PCS, and a third PCS connected via the respective spaced projections or nodules of the first PCS, the second PCS, and the third PCS connected in the interdigitated manner to form a three-sided substrate assembly.

6. The substrate assembly of claim 1, wherein:
the plurality of PCS' include a first PCS, a second PCS, a third PCS, and a fourth PCS;
wherein the second and fourth PCS' have a first subset of their respective spaced projections or nodules connected in the interdigitated manner with a subset of spaced projections or nodules of the first PCS; and
the second and fourth PCS' have a second subset of their respective spaced projections or nodules connected in the interdigitated manner with a subset of spaced projections or nodules of the third PCS to form a four-sided substrate assembly.

7. The substrate assembly of claim 6, wherein the four-sided substrate assembly has the form of an open box including four sides, an open top, and an open bottom, wherein the four sides of the open box define an opening that extends between the open top and the open bottom.

8. The substrate assembly of claim 6, further including;
a fifth PCS connected via the spaced projections or nodules of the fifth PCS in the interdigitated manner to a first subset of the spaced projections or nodules of the first, second, third, and fourth PCS'; and
a sixth PCS connected via the spaced projections or nodules of the sixth PCS in the interdigitated manner to a second subset of the spaced projections or nodules of the first, second, third, and fourth PCS' to form a six-sided substrate assembly.

9. The substrate assembly of claim 7, further including an internal conduit, tube, or pipe positioned through the opening between the open top and the open bottom.

10. The substrate assembly of claim 9, further including thermal packing between the internal conduit, tube, or pipe and the PCS' forming the four sides of the open box.

11. The substrate assembly of claim 7, further including an external conduit, tube, or pipe surrounding the sides of the four-sided substrate assembly in the form of the open box.

12. The substrate assembly of claim 11, further including thermal packing between the external conduit, tube, or pipe and the PCS' forming the four sides of the open box.

13. The substrate assembly of claim 7, further comprising a pair of the four-sided substrate assemblies in the form of open boxes connected together via a subset of the spaced projections or nodules of the PCS' comprising the pair of the four-sided substrate assemblies with the openings of the pair of the four-sided substrate assemblies positioned in series.

14. The substrate assembly of claim 13, further including an internal conduit, tube, or pipe positioned through the openings of the pair of the four-sided substrate assemblies positioned in series.

15. The substrate assembly of claim 14, further including thermal packing between the internal conduit, tube, or pipe and the PCS' forming the pair of the four-sided substrate assemblies.

16. The substrate assembly of claim 13, further including an external conduit, tube, or pipe surrounding the sides of the pair of four-sided substrate assemblies.

17. The substrate assembly of claim 16, further including thermal packing between the external conduit, tube, or pipe and the PCS' forming the pair of the four-sided substrate assemblies.

18. The substrate assembly of claim 7, further comprising:
a first pair of the four-sided substrate assemblies in the form of open boxes connected together via a subset of the spaced projections or nodules of the PCS' comprising the first pair of the four-sided substrate assemblies with the openings of the first pair of the four-sided substrate assemblies positioned in series; and
a second pair of the four-sided substrate assemblies in the form of open boxes connected together via a subset of the spaced projections or nodules of the PCS' comprising the second pair of the four-sided substrate assemblies with the openings of the second pair of the four-sided substrate assemblies positioned in series;
wherein the first and second pairs of the four-sided substrate assemblies are connected side-by-side with the openings of the first pair of the four-sided substrate assemblies positioned in series running in the same direction as the openings of the second pair of the four-sided substrate assemblies positioned in series.

19. The substrate assembly of claim 1, wherein the plurality of PCS' include:
a first PCS and a second PCS connected in a plane or straight line to each other via the respective spaced projections or nodules of the first PCS and the second PCS connected in the interdigitated manner; and
a third PCS connected at a transverse or right angle to the first PCS and the second PCS, wherein the spaced projections or nodules of the third PCS are connected to the interdigitated connection of the respective spaced projections or nodules of the first PCS and the second PCS to form a T-shaped or substantially T-shaped substrate assembly

20. The substrate assembly of claim 19, wherein the spaced projections or nodules of the first PCS and the second PCS connected in the interdigitated manner include at least one of the spaced projections or nodules of the first PCS is shorter than the spaced projections or nodules of the second PCS disposed on opposite sides of the at least one spaced projection or nodule of the first PCS whereupon a gap exists between a distal end of the at least one spaced projection or nodule of the first PCS and the side surface of the second PCS, and at least one of the spaced projections or nodules of the third PCS is inserted in this gap.
